(19) United States
(12) Patent Application Publication
(10) Pub. No.: US 2006/0082978 A1
(43) Pub. Date: Apr. 20, 2006

(54) ELECTRONIC DEVICE HAVING A JACKET CAPABLE OF BEING ATTRACTED TO A MAIN BODY

(76) Inventors: Chien-Jui Wang, Taipei City (TW); Chia-Chuan Lin, Taipei Hsien (TW); Hung-Ming Chen, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/163,054

(22) Filed: Oct. 3, 2005

(30) Foreign Application Priority Data
Oct. 18, 2004 (TW) 093131570

(51) Int. Cl. H05K 5/03

(52) U.S. Cl. 361/728; 361/747

(57) ABSTRACT

An electronic device includes a main body for performing functions of the electronic device, and a jacket having a first end coupled to the main body and a second end attracted to the main body through a magnetic force.

### BACKGROUND OF THE INVENTION

1. Field of the Invention

The invention relates to an electronic device, and more particularly, to an electronic device having a jacket attracted to the main body.

2. Description of the Prior Art

As information technology has increasingly become digital, electronic devices have developed rapidly. Additionally, as digital technology has become prevalent, hand-held devices have become more and more portable. Examples of such hand-held devices are MP3 (Moving Picture Experts Group, MPEG1, layer 3) players, personal disks, etc.

Please refer to FIG. 1. FIG. 1 is a diagram of a related art portable electronic device 100. According to FIG. 1, the portable electronic device includes a USB interface connector 110 for connecting the device with a main machine (such as a computer). This allows electronic information to be transmitted from the computer to the portable electronic device 100. Electronic information can also be transmitted from the portable electronic device 100 to the computer via the same route. The portable electronic device 100 is popular with users because of its volume. However, when utilized in a non-static environment, the portable electronic device 100 may be unstable. For example, the electronic device 100 can be securely placed in a static environment, but when it is utilized in a non-static environment (e.g. jogging, walking, dancing) it needs careful attention to prevent the electronic device 100 from falling, and therefore becomes burdensome to the user.

### SUMMARY OF THE INVENTION

One objective of the claimed invention is therefore to provide an electronic device having a jacket attracted to the main body, which can be attached to all kinds of fittings such as clothing, hats, or backpacks to solve the above-mentioned problem.

According to an exemplary embodiment of the claimed invention, an electronic device having a jacket attracted to the main body is disclosed. The electronic device comprises a main body for executing functions of the electronic device; and a jacket having a first end coupled to the main body and a second end attracted to the main body through a magnetic force. The material of one side of the main body's housing is metal; the second side end of the jacket comprises a magnetic element, and there is a strong magnetic force between the two sides.

It is an advantage of the present invention that the magnetic force between the main body and the jacket can enable any kinds of fittings to be attached to the electronic device, whilst fulfilling the requirement for a user in a non-static state of not dropping the electronic device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a prior art portable electronic device.

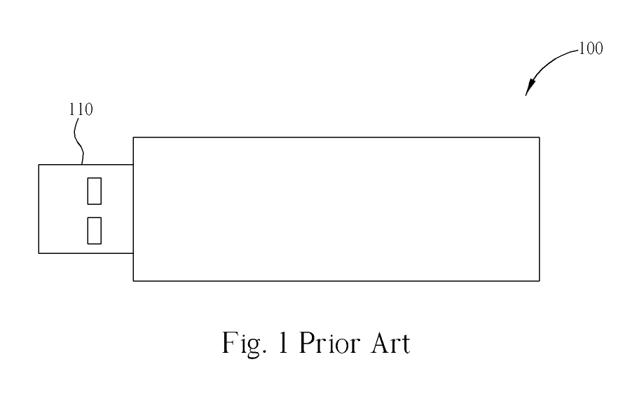

FIG. 2 is a front view of an electronic device according to an exemplary embodiment of the present invention.

FIG. 3 is a rear view of an electronic device according to an exemplary embodiment of the present invention.

FIG. 4 is a side view of an electronic device according to an exemplary embodiment of the present invention.

### DETAILED DESCRIPTION

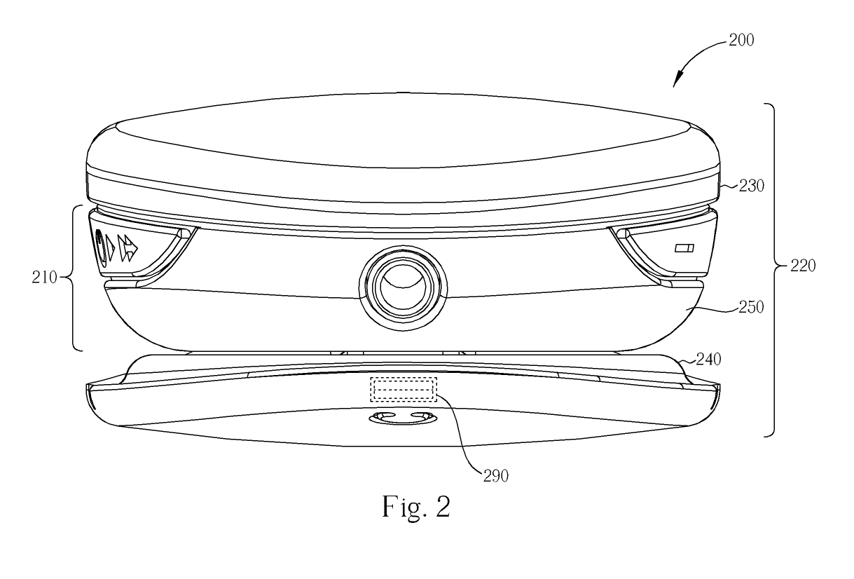

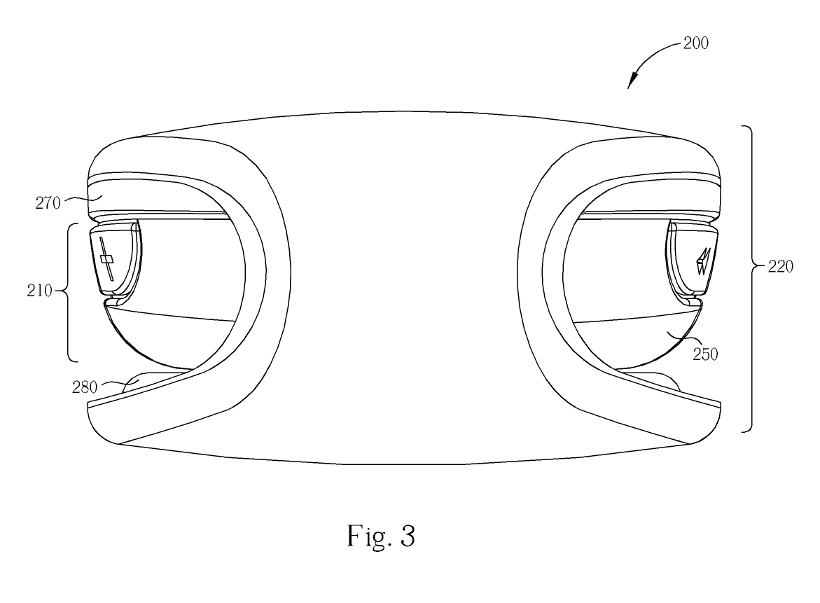

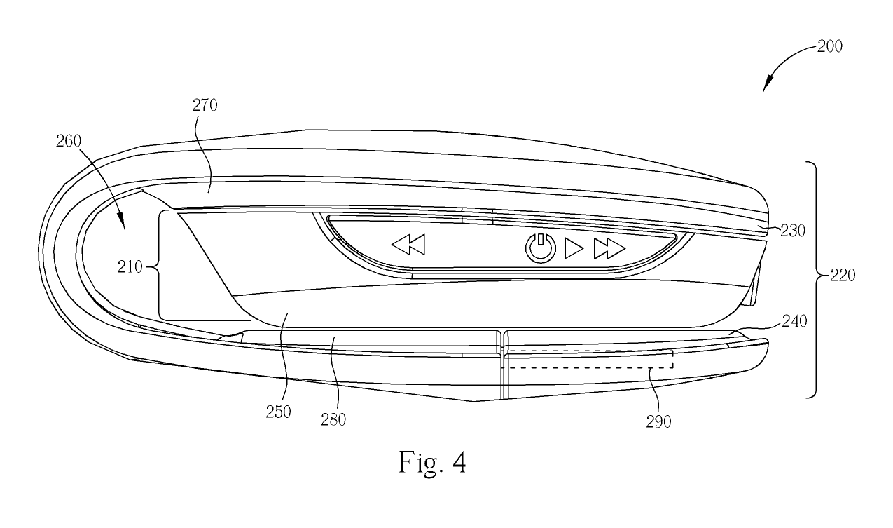

Please refer to FIG. 2, FIG. 3 and FIG. 4. FIG. 2, FIG. 3 and FIG. 4 are the front view, rear view and side view respectively of the present invention electronic device 200. The electronic device 200 is a hand-held device comprising a main body 210 and a jacket 220. The main body 210 is for executing functions of the electronic device 200. For example, the main body 210 can bean MP3 player or a personal disk. The jacket 220 has a first end 230 and a second end 240. The first end 230 is connected to the main body 210, and the second end 240 is attracted to the main body 210 through a magnetic force. Please note that the magnetic force is larger than the weight of the electronic device 200.

The jacket 220 further comprises a first surface 270 and a second surface 280. The surface 270 is close to the first end 230 and connected to a corresponding side of the main body 210. The second surface 280 is close to the second end 240 and connected to another corresponding side of the main body 210. The first surface 270 and the second surface 280 of the main body 210 can both be flat surfaces or curved surfaces in order to connect. The generated magnetic force when the first surface 270 and the second surface 280 are both curved surfaces is larger than the generated magnetic force when the first surface 270 and the second surface 280 are both flat surfaces. Additionally, the jacket 220 further comprises a spacing part 260 connected to the first surface 270 and the second surface 280 for hanging the electronic device by the joining of a rope or a chain. Therefore the electronic device 200 can be easily hung on a user's body. The second end 240 further comprises an input/output surface 290, which is electrically connected through the first end 230 to the main body 210. The input/output surface could be a USB surface or other kinds of input/output surfaces.

In the first embodiment of the present invention electronic device 200, the housing side 250 of the main body 210 is metal, and the second end 240 of the jacket 220 comprises a magnetic element such as a magnet. There is therefore a strong magnetic force between the side 250 and the second end 240. If a user places a fitting such as clothing, a hat, or a backpack between the side 250 and the second end 240, the electronic device 200 will be strongly attracted to the user's fitting through the strong magnetic force.

In the second embodiment of the present invention electronic device 200, the main body 210 comprises a magnetic element such as a magnet, and the second end 240 of the jacket 220 comprises a metal element such as an iron sheet. The magnetic element of the main body 210 and the metal element of the second end 240 are therefore attracted to each other through a magnetic force. As in the first embodiment, if a user places a fitting such as clothing, a hat, or a backpack between the side 250 and the second end 240, the electronic device 200 will be strongly attracted to the user's fitting through the strong magnetic force.

In the third embodiment of the present invention electronic device 200, the housing side 250 of the main body 210 is magnetic, and the second end 240 of the jacket 220 comprises a magnetic element such as a magnet. There is therefore a strong magnetic force between the side 250 and the second end 240. If a user places a fitting such as clothing, a hat, or a backpack between the side 250 and the second end 240, the electronic device 200 will be strongly attracted to the user's fitting through the strong magnetic force.

In the fourth embodiment of the present invention electronic device 200, the main body 210 comprises a magnetic element such as a magnet, and the second end 240 comprises another magnetic element such as a magnet. The magnetic elements in the main body 210 and the second end 240 are therefore attracted to each other through a magnetic force. If a user places a fitting such as clothing, a hat, or a backpack between the side 250 and the second end 240, the electronic device 200 will be strongly attracted to the user's fitting through the strong magnetic force.

Please note that the first embodiment uses a metal material (in the main body 210) and a magnetic element (in the jacket 220) to generate the needed magnetic force; the second embodiment uses a metal element (in the jacket 220) and a magnetic element (in the main body 210) to generate the needed magnetic force; the third embodiment uses a metal element (in the jacket 220) and a magnetic material (in the main body 210) to generate the needed magnetic force; and the fourth embodiment uses two magnetic elements (both in the main body 210 and the jacket 220) to generate the needed magnetic force. The type of magnetic force between the second end 240 of the jacket 220 and the main body 210 is not limited, however. Any kind of magnetic force can be applied between the second end 240 of the jacket 220 and the main body 210 in order to provide attraction between the jacket 220 and the main body 210.

Compared to the prior art, the present invention through the magnetic force between the main body and the jacket can allow a user to be in motion without dropping the electronic device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device comprising:
a main body for executing functions of the electronic device; and
a jacket having a first end coupled to the main body and a second end attracted to the main body through a magnetic force.

2. The electronic device of claim 1, wherein the second end further comprises an input/output surface that is electronically connected through the first end to the main body.

3. The electronic device of claim 2, wherein the input/output surface is a USB interface.

4. The electronic device of claim 1, wherein the main body has a housing, of which one side is metal, the second end of the jacket comprises a magnetic element, and the metal side of the housing is attracted to the magnetic element through the magnetic force.

5. The electronic device of claim 1, wherein the main body further comprises a magnetic element, the second end of the jacket further comprises a metal element, and the magnetic element is attracted to the metal element through the magnetic force.

6. The electronic device of claim 1, wherein the main body has a housing with one side being magnetic, the second end of the jacket further comprises a metal element, and the magnetic side of the housing is attracted to the metal element through the magnetic force.

7. The electronic device of claim 1, wherein the main body further comprises a first magnetic element, the second end further comprises a second magnetic element, and the first magnetic element and the second magnetic element are attracted to each other through the magnetic force.

8. The electronic device of claim 1, wherein the jacket further comprises:
a first surface close to the first end and connected to a first side of the main body; and
a second surface close to the second end and connected to a second side of the main body through the magnetic force.

9. The electronic device of claim 8, wherein the second surface and the second side of the main body are curved surfaces.

10. The electronic device of claim 9, wherein the jacket further comprises:
a spacing part connected to the first surface and the second surface for hanging the electronic device by attaching a rope.

11. The electronic device of claim 1, wherein the magnetic force is larger than the weight of the electronic device.

12. The electronic device of claim 1, wherein the electronic device is a kind of hand-held electronic device.

13. The electronic device of claim 12, wherein the hand-held electronic device is an MP3 player or a personal disk.
